(19) United States
(12) Patent Application Publication
(10) Pub. No.: US 2023/0303389 A1
(43) Pub. Date: Sep. 28, 2023

(54) METHODS AND SYSTEMS FOR FABRICATION OF ULTRASOUND TRANSDUCER DEVICES

(71) Applicant: Exo Imaging, Inc., Redwood City, CA (US)

(72) Inventors: Liang WANG, Newark, CA (US); David KREVOR, San Carlos, CA (US); Naresh MANTRAVADI, San Jose, CA (US); Brian BIRCUMSHAW, Orinda City, CA (US); Jason TAUSCHER, Sammamish, WA (US)

(21) Appl. No.: 17/702,599

(22) Filed: Mar. 23, 2022

(51) Int. Cl. B81C 1/00; B81B 7/00

(52) U.S. Cl. CPC B81C 1/00825; B81B 7/0016; B81B 2201/0271; B81B 2207/012; B81C 2203/0792

(57) ABSTRACT

Described herein are methods and systems useful in the fabrication of ultrasound transducer devices. Fabrication of ultrasound transducer devices can comprise manipulation of components having extremely small cross-sectional thicknesses, which can increase the risk of damage to the components. For example, inadvertent application of forces sufficient to damage such components is a significant risk during fabrication steps. As described herein, the risk of damage to an ultrasound transducer device component having a small cross-sectional thickness, such as an ultrasound microelectromechanical system (MEMS) wafer, can be reduced by partially or completely coating or filling all or a portion of the component with a stabilizing material, for example, prior to subjecting the component to forces associated with manipulation of the component during the fabrication process.

### BACKGROUND

Sensitive components of ultrasound transducers can be damaged during fabrication using conventional methods and systems, for example, by inadvertent bending of the components during the fabrication process. In some cases, enough of an ultrasound transducer device's array membranes can be damaged during fabrication that the device becomes unreliable or unusable. Repair of transducer components damaged during fabrication can be time-intensive and costly. In some cases, transducer array components damaged during fabrication cannot be repaired, and the unit must be discarded, reducing manufacturing yield. In some cases, it cannot be determined whether an ultrasound device component has been damaged during fabrication to the point that an ultrasound transducer device must be discarded until after the device has been fully assembled and tested, increasing per unit cost. Thus, in many cases, ultrasound device manufacturers using existing ultrasound device fabrication methods and systems must absorb the costs of units lost to unusable or unreliable devices having components damaged during fabrication. Hence, improved systems and methods for fabricated transducer devices are desired.

### SUMMARY

Fabrication of an ultrasound transducer device can involve manipulation of delicate device components (e.g., one or more ultrasound transducer device components at risk of fracture or breakage, for instance, due to application of mechanical force to the component(s)). For example, microelectromechanical system (MEMS) components used in generating and/or receiving ultrasound wave energy during operation of an ultrasound transducer device can have one or more cross-sectional dimensions (e.g., a cross-sectional thickness) that leave the component susceptible to damage from a force applied to the component. Existing techniques for ultrasound transducer device fabrication can involve application of force to such ultrasound transducer device components (e.g., during application of a component to a substrate, release of a component from a temporary substrate, and/or translation of the component from one location to another during fabrication), which can increase the risk of damage (e.g., fracture or breakage) of the components. In practice, damage to components during ultrasound transducer device fabrication can affect the function of the ultrasound transducer device and can result in substantial and costly overall losses in product production.

As described herein, the risk of damage to a component during fabrication can be decreased by mechanically stabilizing the component during fabrication. For instance, a component can be mechanically stabilized by adding a stabilizing material to the component (e.g., by partially or completely coating or filling all or a portion of the component with the stabilizing material). In some cases, a stabilizing material can be added to a component prior to a fabrication step involving physical manipulation of the component, such as the component to a structural support (e.g., a carrier substrate), releasing the component from a structural support, and/or attaching the component to one or more additional device components, e.g., to reduce a risk of damage (e.g., fracture or breakage of a portion of the component).

In various aspects, a method of fabricating an ultrasound transducer device, the method comprises: forming a plurality of cavities in a transducer wafer coupled to a carrier substrate; contacting one or more inner surfaces of one or more of the plurality of cavities with a stabilizing material; and decoupling the transducer wafer from the carrier substrate after contacting the one or more inner surfaces with the stabilizing material. In some cases, the method comprises reducing a cross-sectional thickness of at least a portion of the transducer wafer. In some cases, the cross-sectional thickness of the transducer wafer is reduced to no more than 75 micrometers. In some cases, the cross-sectional thickness of the transducer wafer is reduced to no more than 50 micrometers. In some cases, reducing the cross-sectional thickness of at least a portion of the transducer wafer is performed before forming the plurality of cavities in the transducer wafer. In some cases, reducing the cross-sectional thickness of at least a portion of the transducer wafer is performed after forming the plurality of cavities in the transducers wafer. In some cases, reducing the cross-sectional thickness of at least a portion of the transducer wafer is performed after contacting the one or more inner surfaces with the stabilizing material. In some cases, reducing the cross-sectional thickness of at least a portion of the transducer wafer is performed before contacting the one or more inner surfaces with the stabilizing material. In some cases, the plurality of cavities is formed in the transducer wafer using photolithography. In some cases, forming the plurality of cavities in the transducer wafer comprises etching the plurality of cavities in the transducer wafer. In some cases, reducing the cross-sectional thickness of at least a portion of the transducer wafer comprises backgrinding a surface of the transducer wafer. In some cases, reducing the cross-sectional thickness of at least a portion of the transducer wafer comprises etching a cavity side wall of the transducer wafer. In some cases, the etching comprises wet etching or plasma etching. In some cases, the transducer wafer coupled to the carrier comprises a cross-sectional thickness of 100 micrometers. In some cases, the transducer wafer coupled to the carrier comprises a cross-sectional thickness of 75 micrometers. In some cases, the transducer wafer coupled to the carrier comprises a cross-sectional thickness of 50 micrometers. In some cases, contacting one or more inner surfaces with the stabilizing material comprises one or more of spin coating, ink jet deposition, spray deposition, physical vapor deposition (PVD), or chemical vapor deposition (CVD). In some cases, the method further comprises polymerizing the stabilizing material. In some cases, polymerizing the stabilizing material is performed after contacting the one or more inner surfaces with the stabilizing material. In some cases, polymerizing the stabilizing material is performed at the same time as contacting the one or more inner surfaces with the stabilizing material. In some cases, polymerizing the stabilizing material comprises exposing the stabilizing material to ultraviolet (UV) light. In some cases, contacting one or more inner surfaces with stabilizing material comprises filling the one or more cavities with stabilizing material until the stabilizing material is even with the height of one or more cavity side walls of the one or more cavities. In some cases, contacting one or more inner surfaces with stabilizing material comprises filling the one or more cavities with stabilizing material until the stabilizing material exceeds the height of one or more cavity side walls of the one or more cavities. In some cases, contacting one or more inner surfaces with stabilizing material comprises filling the one or more cavities with stabilizing material until the stabilizing material less than the height of one or more cavity side walls of the one or more cavities. In some cases, the method further comprises singulating the transducer wafer into one or more ultrasound transducer chips comprising the plurality of cavities and the stabilizing material; and coupling an acoustic lens coupled to one or more of the stabilizing material or a transducer chip of the one or more ultrasound transducer chips. In some cases, the acoustic lens extends above and across each of the one or more cavities. In some cases, the acoustic lens is formed from the same material as the stabilizing material. In some cases, the acoustic lens is formed from a material different than the stabilizing material. In some cases, the ultrasound lens is formed from a lens material, and wherein the lens material and the stabilizing material have one or more of a sound speed, acoustic attenuation, or acoustic impedance that are substantially the same. In some cases, the method further comprises coupling one or more ultrasound transducer chips comprising the plurality of cavities and the stabilizing material singulated from the transducer wafer to an application-specific integrated circuit (ASIC). In some cases, one or more ultrasound transducer chips are coupled to the ASIC by flip-chip soldering. In some cases, the stabilizing material has a decomposition temperature higher than a reflow temperature of a solder used to couple the one or more ultrasound transducer chips to the ASIC. In some cases, the method further comprises coupling the ASIC to a printed circuit board (PCB). In some cases, the ASIC is coupled to the PCB by wirebonding or by flip-chip soldering. In some cases, the stabilizing material has a decomposition temperature higher than a reflow temperature of a solder used to couple the ASIC to the PCB. In some cases, the stabilizing material comprises silicone. In some cases, the stabilizing material comprises one or more heat stabilizer additives selected from iron, cerium, and titanium oxide. In some cases, the stabilizing material has a decomposition temperature higher than 240° C. In some cases, the ultrasound transducer device comprises a pMUT transducer. In some cases, the ultrasound transducer device comprises a cMUT transducer.

In various aspects, an ultrasound transducer device comprises: a transducer chip comprising a plurality of cavities; a stabilizing material in contact with at least a portion of an inner surface of one or more of the plurality of cavities; an acoustic lens extending above and across the plurality of cavities and formed from a lens material, wherein the lens material and the stabilizing material have one or more of a sound speed, acoustic attenuation, or acoustic impedance that are substantially the same. In some cases, at least a portion, the device further comprises an application-specific integrated circuit (ASIC) and a printed circuit board (PCB), wherein the ASIC is coupled to the PCB by a junction comprising a solder. In some cases, a decomposition temperature of the stabilizing material is greater than a reflow temperature of the solder. In some cases, the reflow temperature of the solder is 240° C. In some cases, the stabilizing material comprises one or more heat stabilizer additives selected from iron, cerium, and titanium oxide. In some cases, the stabilizing material has a low acoustic attenuation. In some cases, the acoustic lens is formed from a material that is different than the stabilizing material. In some cases, the lens material has a decomposition temperature equal to or greater than the decomposition temperature of the stabilizing material. In some cases, the lens material has a decomposition temperature less than the decomposition temperature of the stabilizing material. In some cases, the transducer chip has a cross-sectional thickness of at most 50 micrometers across an entire length and width of the transducer chip. In some cases, the ultrasound transducer device comprises a pMUT transducer. In some cases, the ultrasound transducer device comprises a cMUT transducer.

### BRIEF DESCRIPTION OF THE DRAWINGS

A better understanding of the features and advantages of the present subject matter will be obtained by reference to the following detailed description that sets forth illustrative embodiments and the accompanying drawings of which:

FIG. 1A and FIG. 1B each show a schematic diagram showing a portion of an ultrasound transducer device, in accordance with embodiments.

FIG. 2A shows a schematic flow chart of exemplary steps useful in the fabrication of an ultrasound transducer device, in accordance with embodiments.

FIG. 2B shows a schematic flow chart of exemplary steps useful in the fabrication of an ultrasound transducer device, in accordance with embodiments.

FIG. 3 shows a schematic flow chart of exemplary steps useful in the fabrication of an ultrasound transducer device, in accordance with embodiments.

FIG. 4 shows a schematic flow chart of exemplary steps useful in the fabrication of an ultrasound transducer device, in accordance with embodiments.

FIG. 5A shows a flow chart of an exemplary method useful in the fabrication of an ultrasound transducer device, in accordance with embodiments.

FIG. 5B shows a flow chart of an exemplary method useful in the fabrication of an ultrasound transducer device, in accordance with embodiments.

FIG. 6 shows a flow chart of an exemplary method useful in the fabrication of an ultrasound transducer device, in accordance with embodiments.

### DETAILED DESCRIPTION

Described herein are methods, systems, and devices useful in reducing the risk of damage to one or more components of an ultrasound transducer device during device fabrication. Ultrasound transducer devices can comprise one or more components susceptible to damage (e.g., via fracture or breakage), for example, if a force (e.g., a normal force and/or a shearing force) is applied to the one or more components at risk of damage (e.g., at a point of the one or more components having a cross-sectional dimension measuring 50 micrometers (μm) or less). As described herein, the risk of damage to one or more components of an ultrasound transducer device can be decreased by mechanically stabilizing the one or more components (or a portion thereof) during fabrication. For instance, MEMS wafers, which can be rendered to thicknesses during ultrasound transducer device fabrication that can leave the wafers susceptible to damage (e.g., 50 micrometers or less), may be partially or completely coated or filled with a material (e.g., a stabilizing material) capable of mechanically stabilizing the MEMS wafer during the fabrication process.

In some cases, the risk of damage to a component of an ultrasound transducer device can be reduced by partially or completely coating or filling the component with a material capable of mechanically stabilizing the component before a fabrication step involving release of the component from a solid support and/or before the application of substantial mechanical forces to the wafer (e.g., prior to manipulation of the wafer), as described herein. In some cases, a material can be capable of mechanically stabilizing a component (or portion thereof) if the material can be used to physically resist bending of the component (e.g., by increasing the effective thickness of all or a portion of the component subjected to a force). In some cases, a material used to mechanically stabilize one or more components of the ultrasound transducer device during fabrication can be selected based on one or more of its material properties, such as melting point, curing time, required curing conditions, ultrasound transmissibility, viscosity, and/or elastic modulus. In some cases, a material used to form the lens of an ultrasound transducer device, which may have properties allowing the material to be coated onto all or a portion of a component or melted into one or more cavities of a component, can be used to mechanically stabilize one or more components of the ultrasound transducer device during fabrication. Using a material with such properties to mechanically stabilize a component (e.g., a MEMS wafer or portion thereof) of an ultrasound transducer device can decrease the risk of damage to the component while avoiding significant detrimental impacts on ultrasound transmission during operation of the device.

In some cases, fabrication of an ultrasound transducer device can comprise rendering a component of the device thinner with respect to a cross-sectional height, width, and/or length of the component (e.g., by back-grinding and/or etching). In some cases, a component of an ultrasound transducer device that comprises a thin cross-sectional dimension (e.g., having a cross-sectional height, length, and/or width of less than or equal to 50 micrometers (μm)) can be susceptible to damage, for example, when a force is applied to the component during the fabrication process (e.g., when the component is released from a carrier substrate, attached to one or more additional ultrasound device components, attached to one or more additional carrier substrates).

### Overview

Methods and systems described herein can comprise one or more ultrasound transducer devices 100 (e.g., ultrasonic transducers). An ultrasound transducer device 100 can be used to transmit ultrasonic energy to and/or receive ultrasonic energy from a target location of a target substance, for instance, to form an image of the target location of the target substance. In some cases, an ultrasound transducer can be useful in imaging a biological tissue, for example, to determine a physiological condition of the biological tissue or of a subject comprising the biological tissue. Ultrasound transducer devices described herein can be portable (e.g., handheld). In some cases, an ultrasound transducer device can be made smaller in size by reducing one or more cross-sectional dimensions (e.g., a cross-sectional thickness) of one or more of the components comprising the ultrasound transducer device. In some cases, reducing the size of an ultrasound transducer device (e.g., by reducing a cross-sectional thickness of one or more ultrasound transducer device components) can render the ultrasound transducer device more maneuverable. In some cases, increasing the maneuverability of an ultrasound transducer device can make the ultrasound transducer device more portable and/or easier to use during imaging procedures.

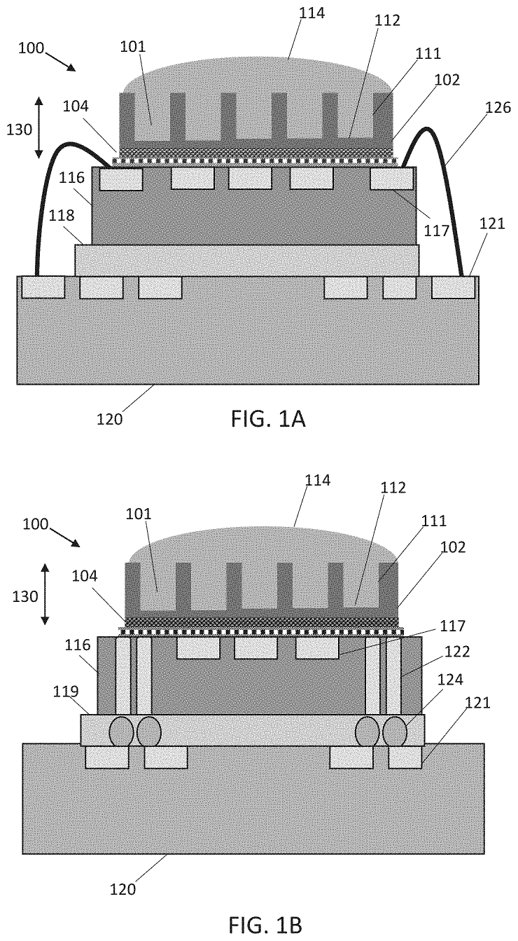

An ultrasound transducer device 100 can comprise an ultrasound transducer wafer 102 (e.g., as shown in FIG. 1A and FIG. 1B). In some cases, an ultrasound transducer wafer 102 can comprise a microelectromechanical system (MEMS) transducer. In some cases, the MEMS transducer can be a piezoelectric micromachine ultrasound transducer (pMUT). In some cases, the MEMS transducer can be a capacitive micromachine ultrasound transducer (cMUT). In some cases, the cross-sectional thickness 130 of an ultrasound transducer wafer 102 or portion thereof can significantly impact the likelihood (e.g., risk) of damaging the ultrasound transducer wafer or portion thereof (e.g., a MEMS transducer or portion thereof) during fabrication. In many cases, preventing damage to an ultrasound transducer wafer 102 during fabrication can be important to preserving the function (e.g., comprising accuracy and/or reliability) of an ultrasound transducer device 100 comprising the ultrasound transducer wafer 102.

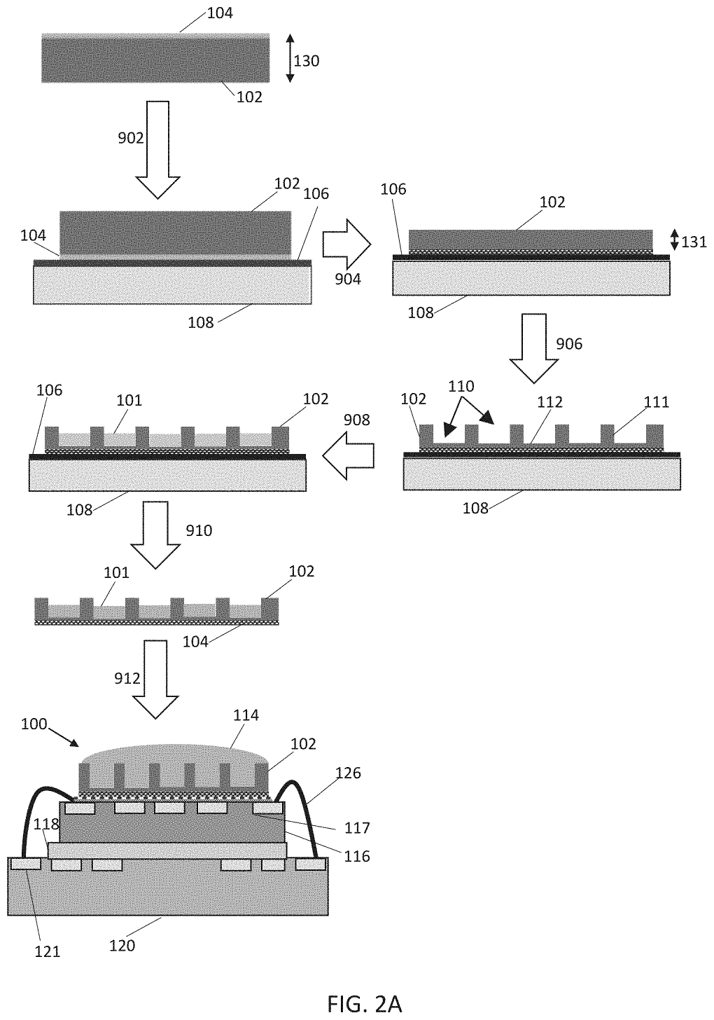

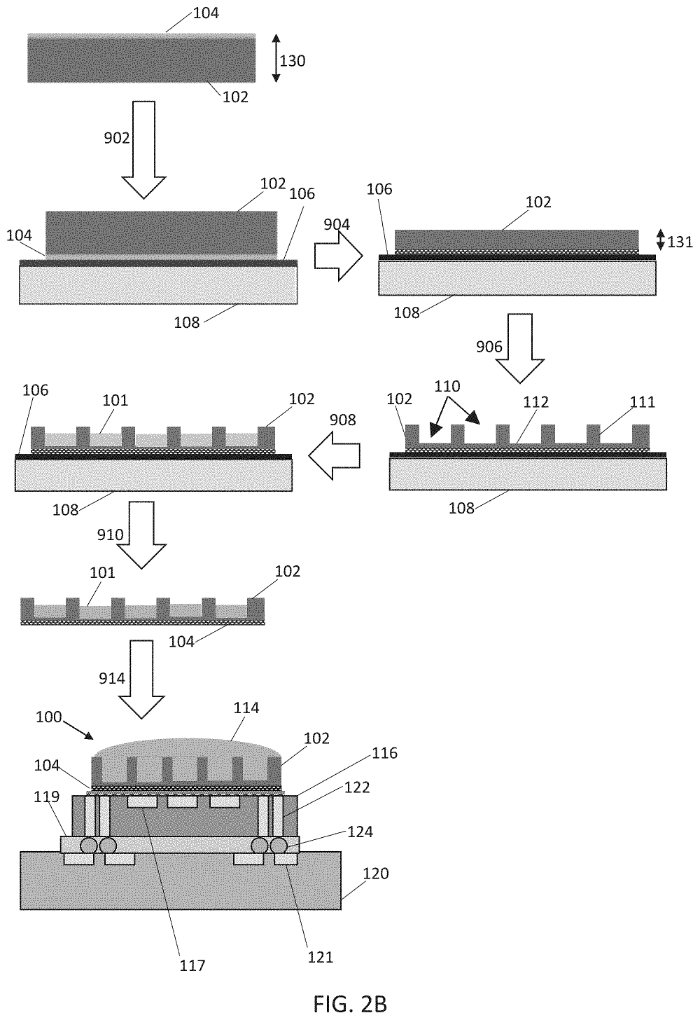

As shown in FIG. 2A and FIG. 2B a method of fabricating an ultrasound transducer device 102 can comprise providing an ultrasound transducer wafer 102 (e.g., a having an initial cross-sectional thickness 130). In some cases, an ultrasound transducer wafer 102 can comprise a metal backing layer 104. In some cases, a method of fabricating an ultrasound transducer device can comprise coupling an ultrasound wafer 102 to a solid support 108 (e.g., a carrier substrate 108), for example, using an adhesive 106 (e.g., as shown in step 902 of FIG. 2A and FIG. 2B). In some cases, an adhesive used to couple an ultrasound transducer wafer 102 to a solid support 108 can be a debondable adhesive. Using a debondable adhesive can facilitate release of the ultrasound transducer wafer 102 from the solid support 108 at a later stage of the fabrication method. In some cases, a method of fabricating an ultrasound transducer device 102 can comprise providing an ultrasound transducer wafer 102 (e.g., having an initial cross-sectional thickness 130) that is already coupled to a solid support 108 (e.g., via an adhesive 106, such as a debondable adhesive 106). A solid support (e.g., carrier substrate) can comprise, e.g., glass or quartz. In some cases, an ultrasound transducer wafer can comprise a silicon layer coupled to the metal backing layer. In some cases, the metal backing layer can be coupled directly to the solid support (e.g., between the silicon layer of the ultrasound transducer wafer and the solid support. In some cases, the ultrasound transducer wafer or a portion thereof (e.g., the metal backing layer) can be coupled to the solid support by an adhesive (e.g., a debondable adhesive).

A method of fabricating an ultrasound transducer device 100 can comprise reducing a cross-sectional thickness of the ultrasound transducer wafer 102 or a portion thereof (e.g., from an initial cross-sectional thickness 130 to a reduced cross-sectional thickness 131). For instance, a method of fabricating an ultrasound transducer device 100 can comprise reducing the thickness of a silicon layer of the ultrasound transducer wafer 102, e.g., from an initial cross-sectional thickness 130 to a reduced cross-sectional thickness 131. Reducing a cross-sectional thickness of an ultrasound transducer wafer 102 can comprise backgrinding the ultrasound transducer wafer 102 or a portion thereof (e.g., a silicon layer of the ultrasound transducer wafer 102). In some cases, reducing a cross-sectional thickness of an ultrasound transducer wafer 102 can comprise using photolithography. In some cases, reducing a cross-sectional thickness of an ultrasound transducer wafer 102 can comprise etching the ultrasound transducer wafer 102 or a portion thereof (e.g., using wet etching or plasma etching techniques). In some cases, reducing a cross-sectional thickness of the ultrasound transducer wafer can improve the function of an ultrasound transducer device (e.g., the quality and/or reliability (e.g., reproducibility) of the generation and/or detection of ultrasound energy waves). In some cases, reducing a cross-sectional thickness of an ultrasound transducer wafer 102 can aid in reducing an overall size of an ultrasound transducer device 100.

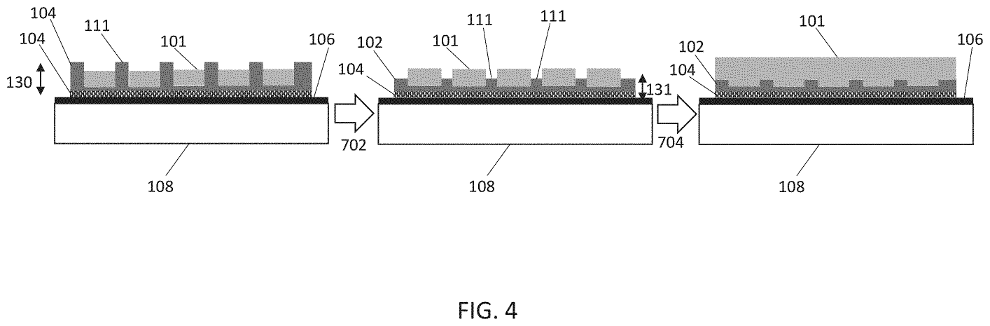

In some cases, a method of fabricating an ultrasound transducer device 100 can comprise reducing a cross-sectional thickness of an ultrasound transducer wafer 102 from an initial cross-sectional thickness 130 to a reduced cross-sectional thickness 131 (e.g., as shown in step 904 of FIG. 2A and FIG. 2B and in step 702 of FIG. 4). In some cases, reducing a cross-sectional thickness can comprise reducing a cross-sectional thickness of an entire width and length of an ultrasound transducer wafer 102 (e.g., as in some cases wherein backgrinding is used to reduce the cross-sectional thickness of the ultrasound transducer wafer 102 prior to cavity formation, for example, as shown in FIG. 2A and FIG. 2B). In some cases, reducing a cross-sectional thickness of an ultrasound transducer wafer 102 can comprise reducing a cross-sectional thickness of one or more portions of the ultrasound transducer wafer 102 (e.g., wherein the cross-sectional thickness of cavity side walls is reduced after cavity formation in the ultrasound transducer wafer 102, for example, as shown in FIG. 4). In some cases, an ultrasound transducer wafer can comprise a cross-sectional thickness of from 20 micrometers (μm) to 100 micrometers, from 20 micrometers to 75 micrometers, from 30 micrometers to 75 micrometers, from 40 micrometers to 75 micrometers, from 50 micrometers to 75 micrometers, or from 40 micrometers to 50 micrometers. In some cases, a method of fabricating an ultrasound transducer device 100 can comprise providing an ultrasound transducer wafer 102 (e.g., coupled to a carrier substrate 108) at an initial cross-sectional thickness of greater than 100 micrometers, at least 100 micrometers, at least 75 micrometers, at least 50 micrometers, at least 40 micrometers, at least 30 micrometers, or at least 20 micrometers. In some cases, a method of fabricating an ultrasound transducer device 100 can comprise reducing a cross-sectional thickness of an ultrasound transducer wafer 102 to a cross-sectional thickness (e.g., a reduced cross-sectional thickness) of 1 to 100 micrometers. In some cases, a method of fabricating an ultrasound transducer device 100 can comprise reducing a cross-sectional thickness of an ultrasound transducer wafer 102 to a cross-sectional thickness (e.g., a reduced cross-sectional thickness) of 1 to 50 micrometers. In some cases, reducing a cross-sectional thickness of an ultrasound transducer wafer 102 can comprise reducing the cross-sectional thickness to a value from about 1 micrometer to about 120 micrometers. In some cases, reducing a cross-sectional thickness of an ultrasound transducer wafer 102 can comprise reducing the cross-sectional thickness to a value from about 1 micrometer to about 20 micrometers, about 1 micrometer to about 30 micrometers, about 1 micrometer to about 40 micrometers, about 1 micrometer to about 50 micrometers, about 1 micrometer to about 60 micrometers, about 1 micrometer to about 75 micrometers, about 1 micrometer to about 85 micrometers, about 1 micrometer to about 100 micrometers, about 1 micrometer to about 110 micrometers, about 1 micrometer to about 120 micrometers, about 20 micrometers to about 30 micrometers, about 20 micrometers to about 40 micrometers, about 20 micrometers to about 50 micrometers, about 20 micrometers to about 60 micrometers, about 20 micrometers to about 75 micrometers, about 20 micrometers to about 85 micrometers, about 20 micrometers to about 100 micrometers, about 20 micrometers to about 110 micrometers, about 20 micrometers to about 120 micrometers, about 30 micrometers to about 40 micrometers, about 30 micrometers to about 50 micrometers, about 30 micrometers to about 60 micrometers, about 30 micrometers to about 75 micrometers, about 30 micrometers to about 85 micrometers, about 30 micrometers to about 100 micrometers, about 30 micrometers to about 110 micrometers, about 30 micrometers to about 120 micrometers, about 40 micrometers to about 50 micrometers, about 40 micrometers to about 60 micrometers, about 40 micrometers to about 75 micrometers, about 40 micrometers to about 85 micrometers, about 40 micrometers to about 100 micrometers, about 40 micrometers to about 110 micrometers, about 40 micrometers to about 120 micrometers, about 50 micrometers to about 60 micrometers, about 50 micrometers to about 75 micrometers, about 50 micrometers to about 85 micrometers, about 50 micrometers to about 100 micrometers, about 50 micrometers to about 110 micrometers, about 50 micrometers to about 120 micrometers, about 60 micrometers to about 75 micrometers, about 60 micrometers to about 85 micrometers, about 60 micrometers to about 100 micrometers, about 60 micrometers to about 110 micrometers, about 60 micrometers to about 120 micrometers, about 75 micrometers to about 85 micrometers, about 75 micrometers to about 100 micrometers, about 75 micrometers to about 110 micrometers, about 75 micrometers to about 120 micrometers, about 85 micrometers to about 100 micrometers, about 85 micrometers to about 110 micrometers, about 85 micrometers to about 120 micrometers, about 100 micrometers to about 110 micrometers, about 100 micrometers to about 120 micrometers, or about 110 micrometers to about 120 micrometers. In some cases, reducing a cross-sectional thickness of an ultrasound transducer wafer 102 can comprise reducing the cross-sectional thickness to a value from about 1 micrometer, about 20 micrometers, about 30 micrometers, about 40 micrometers, about 50 micrometers, about 60 micrometers, about 75 micrometers, about 85 micrometers, about 100 micrometers, about 110 micrometers, or about 120 micrometers. In some cases, reducing a cross-sectional thickness of an ultrasound transducer wafer 102 can comprise reducing the cross-sectional thickness to a value from at least about 1 micrometer, at least about 20 micrometers, at least about 30 micrometers, at least about 40 micrometers, at least about 50 micrometers, at least about 60 micrometers, at least about 75 micrometers, at least about 85 micrometers, at least about 100 micrometers, at least about 110 micrometers, or at least about 120 micrometers. In some cases, reducing a cross-sectional thickness of an ultrasound transducer wafer 102 can comprise reducing the cross-sectional thickness to a value from at most about 20 micrometers, at most about 30 micrometers, at most about 40 micrometers, at most about 50 micrometers, at most about 60 micrometers, at most about 75 micrometers, at most about 85 micrometers, at most about 100 micrometers, at most about 110 micrometers, or at most about 120 micrometers. A method of fabricating an ultrasound transducer device 100 can have a tolerance of plus-or-minus 10 micrometers, plus-or-minus 5 micrometers, plus-or-minus 1 micrometer, or a value in between any two of those values (e.g., a tolerance from 5 to 10 micrometers, from 1 to 10 micrometers, or from 1 to 5 micrometers) with respect to a cross-sectional thickness to which an ultrasound transducer wafer 102 can be reduced. In some cases, reducing a cross-sectional thickness of an ultrasound transducer wafer 102 can increase the risk of damage to the ultrasound transducer wafer 102 (e.g., by decreasing its ability to resist torquing, torsional, or bending forces, which may damage a portion of the transducer wafer).

In some cases, a method of fabricating an ultrasound transducer device can comprise providing an ultrasound transducer wafer comprising one or more cavities 110. Cavities 110 in an ultrasound transducer wafer 102 can aid in the transmission of ultrasound energy to and/or from an ultrasound transducer membrane (e.g., diaphragm) of an ultrasound transducer device 100. For instance, the lumen of the cavity 110 (which can be partially or completely filled with a material having low acoustic attenuation, such as a stabilizing material 101) can serve as a conduit or pathway for ultrasound energy entering or leaving a distal end of an ultrasound transducer device 100 (e.g., via an acoustic lens 114). In many cases, providing one or more such pathways (e.g., in the form of one or more cavities 110, which can each be spatially aligned with, and optionally coupled to, a pMUT or cMUT transducer element in an ultrasound transducer device 100) can allow for or improve generation, detection, and/or transmission of ultrasound energy by the transducer elements of the ultrasound transducer device 100 (e.g., as compared to the use of a wafer that does not comprise cavities). (e.g., a plurality of cavities, for instance, comprising an array). A cavity 110 of an ultrasound transducer wafer 102 can comprise an inner lumen. A cavity 110 of an ultrasound transducer wafer 102 can comprise a plurality of inner surfaces. For instance, a cavity 110 of an ultrasound transducer wafer 102 can comprise an inner surface of a bottom of the cavity 110 and one or more cavity side wall inner surfaces. In some cases, a bottom wall of a cavity 110 of an ultrasound transducer wafer cavity can be actuated (e.g., by one or more piezoelectric actuators, which may be driven by an ASIC and/or a computer system), for example, to generate an ultrasound energy signal for transmission to a target substance.

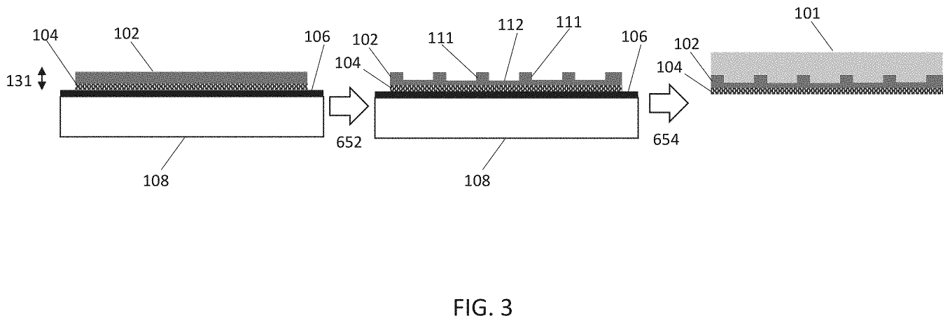

In some cases, a process of fabricating an ultrasound transducer device 100 can comprise forming one or more cavities 110 in an ultrasound transducer wafer 102 (e.g., as shown in step 906 of FIG. 2A and FIG. 2B and in step 652 of FIG. 3). In some cases, a plurality of cavities can be formed in an ultrasound transducer wafer 102. In some cases, the plurality of cavities can be formed in the ultrasound transducer wafer 102 in an array pattern (e.g., wherein the array corresponds to an array of an ASIC 116 to which the ultrasound transducer wafer 102 will be coupled during the fabrication process). In some cases, one or more cavities 110 can be formed in the ultrasound transducer wafer 102 or a portion thereof (e.g., a silicon layer of the ultrasound transducer wafer 102) using photolithography. In some cases, photolithography can comprise the use of masks or patterns to prevent exposure of unintended regions to the photolithography energy. In some cases, one or more cavities 110 can be formed in the ultrasound transducer wafer 102 by etching the ultrasound transducer wafer 102 (e.g., a silicon layer of the ultrasound transducer wafer 102), for example, using wet etching or plasma etching.

In some cases, reducing a cross-sectional thickness (e.g., height) of an ultrasound transducer wafer or cavity side wall thereof can help to reduce the overall size of the ultrasound transducer device and/or improve the performance of the MEMS transducer array. In some cases, reducing a cross-sectional thickness of the ultrasound transducer wafer (e.g., during fabrication) can increase a risk of damage (e.g., fracture or breakage) to the ultrasound transducer wafer (for example, during steps of the fabrication process in which the transducer wafer is not mechanically supported, e.g., by a carrier substrate). In some cases, reduction of a cross-sectional thickness of an ultrasound transducer wafer 102 can increase the likelihood of fracture or breakage of an ultrasound transducer wafer or a portion thereof (e.g., a transducer membrane comprising a bottom wall of a transducer wafer cavity) during fabrication of an ultrasound transducer device 100 (e.g., during wafer processing). For example, reduction of a cross-sectional thickness of an ultrasound transducer wafer (e.g., to 50 micrometers (m) or less, for example, from an initial cross-sectional thickness of 100 micrometers or more) can cause the wafer to become more flexible, which can increase the likelihood of fracture or breakage of an ultrasound transducer wafer or a portion thereof (e.g., a transducer membrane comprising a bottom wall of a transducer wafer cavity) if subjected to even modest forces, such as those associated with ultrasound transducer device fabrication, such as debonding the transducer wafer from a carrier substrate and/or physically transferring the ultrasound transducer wafer to a different substrate (e.g., an ASIC). In some cases, risk of damage to an ultrasound transducer wafer 102 during fabrication can depend on the ratio of a cross-sectional thickness of the wafer to a width or length of the wafer. In some cases, a first ultrasound transducer wafer 102 having a larger width and or length and the same cross-sectional thicknesses compared to a second ultrasound transducer wafer 102 can have a greater risk of damage during fabrication than the second wafer. In some cases, a first ultrasound transducer wafer 102 having the same length and width dimensions and a small cross-sectional thickness than a second ultrasound transducer wafer 102 can have a greater risk of damage during fabrication. In some cases, fabrication of an ultrasound transducer wafer 102 comprising a thickness of 300 micrometers or less and a width and/or length of 6 inches (or more) can pose a significant risk of damage to the wafer during fabrication (e.g., during unsupported handling or manipulation of the wafer without addition of a stabilizing material), while fabrication of an ultrasound transducer wafer 102 comprising a thickness of 400 micrometers or less and a width and/or length of 8 inches (or more) can pose a significant risk of damage to the wafer during fabrication (e.g., during unsupported handling or manipulation of the wafer without addition of a stabilizing material) as well.

As described herein, the risk of damaging an ultrasound transducer wafer 102 (e.g., during steps of the fabrication process in which the ultrasound transducer wafer 102 is not mechanically supported) can be reduced by adding a stabilizing material 101 to all or a portion of the ultrasound transducer wafer 102. For example, a stabilizing material 101 can be used to coat or fill all or a portion of a surface of an ultrasound transducer wafer with a small cross-sectional thickness (e.g., at most 50 micrometers) to reduce the risk of damage to the wafer 102 during fabrication. In some cases, a stabilizing material can be added to one or more cavities of an ultrasound transducer wafer, e.g., to mechanically stabilize the wafer 102. For example, a stabilizing material can be used to coat a bottom surface of an ultrasound transducer wafer cavity (e.g., before the wafer is released from a carrier substrate) to add mechanical stability to the wafer 102, which can help to resist forces (e.g., torquing, torsional, or bending forces) that may be imparted on the wafer 102. Addition of a stabilizing material to a cavity or portion thereof (e.g., an inner surface of a cavity 110, such as an inner surface of a bottom of a cavity 112) can be especially beneficial in decreasing the risk of damage to an ultrasound transducer wafer 102, as a portion of a silicon ultrasound transducer wafer that has been reduced in cross-sectional thickness (e.g., a bottom wall of a cavity formed during a method of fabrication) can have a higher risk of damage (e.g., breakage or fracture) compared to a silicon ultrasound transducer wafer that has not been reduced in cross-sectional thickness (e.g., a solid, polished silicon wafer).

In some cases, one or more surfaces of the ultrasound transducer wafer 102 can be contacted with (e.g., partially or completely coated with) the stabilizing material 101, for instance, before the ultrasound transducer wafer 102 (which may have a cross-sectional thickness of 50 micrometers or less, 40 micrometers or less, 30 micrometers or less, or 20 micrometers or less) is decoupled from a solid support 108 (e.g., as shown in step 908 of FIG. 2A and FIG. 2B, and in step 704 of FIG. 4). For example, a method of fabricating an ultrasound transducer device 100 can comprise contacting one or more inner surfaces of a cavity 110 (e.g., of a plurality of cavities 110) of an ultrasound transducer wafer 102 with a stabilizing material 101 (e.g., before decoupling the wafer 102 from a solid support 108). In some cases, contacting one or more inner surfaces (e.g., of a cavity 110) with stabilizing material comprises filling the one or more cavities with stabilizing material until the stabilizing material is even with the height of one or more cavity side walls of the one or more cavities. In some cases, contacting one or more inner surfaces (e.g., of a cavity 110) with stabilizing material comprises filling the one or more cavities with stabilizing material until the stabilizing material exceeds the height of one or more cavity side walls of the one or more cavities. In some cases, contacting one or more inner surfaces (e.g., of a cavity 110) with stabilizing material comprises filling the one or more cavities with stabilizing material until the stabilizing material less than the height of one or more cavity side walls of the one or more cavities. In some cases, contacting one or more surfaces of an ultrasound transducer wafer 102 with a stabilizing material 101 can decrease the risk of damage to the ultrasound transducer wafer 102 (e.g., resulting from forces applied to the wafer 102 during fabrication steps subsequent to release of the wafer 102 from a solid support 108). In some cases, an inner surface of a bottom wall of a cavity 110 of an ultrasound transducer wafer 102 can be completely coated with stabilizing material 101. In some cases, a cavity 110 of an ultrasound transducer wafer 102 can be partially filled with stabilizing material 101 (e.g., such that the stabilizing material 101 covers an entire inner surface of a bottom wall of the ultrasound transducer wafer 102 but does not contact the entire height of one or more cavity side walls 111, for example, as shown in FIG. 2A and FIG. 2B). In some cases, a cavity 110 of an ultrasound transducer wafer 102 can be completely filled with stabilizing material 101 (e.g., such that the stabilizing material 101 covers an entire inner surface of a bottom wall of the ultrasound transducer wafer 102 and fills the cavity up to the top of the cavity side walls 111, for example, such that the stabilizing material 101 contacting the entire height of one or more cavity side walls 111 of the cavity 110). In some cases, a cavity 110 of an ultrasound transducer wafer 102 can be overfilled with stabilizing material 101 (e.g., such that the stabilizing material 101 completely fills the cavity 110 and covers the tops of one or more cavity side walls 111 of the ultrasound transducer wafer 102, e.g., as shown in FIG. 3). For example, an ultrasound transducer wafer 102 coupled to a solid support 108 can be reduced in cross-sectional thickness (e.g., by backgrinding), for example to a cross-sectional thickness of 50 micrometers or less, before one or more cavities 110 (e.g., an array of cavities 110) are formed in the ultrasound transducer wafer 102 (e.g., by photolithography using a photolithography pattern), e.g., as shown in FIG. 3. In some cases, stabilizing material 101 can be added to partially or completely fill one or more of the cavities 110 after the cross-sectional thickness of one or more cavity side walls 111 has been rendered to a reduced thickness (for example of 50 micrometers or less), e.g., as shown in FIG. 3. In some cases, additional stabilizing material 101 (e.g., having a high decomposition temperature) can be added beyond the thickness of the cavity side walls 111 (e.g., as shown in FIG. 3), for example to form a lens. In some cases, the ultrasound transducer wafer 102 with added stabilizing material 101 can be decoupled from the solid support 108, and in some cases, the ultrasound transducer wafer 102 can be singulated (e.g., by cutting or dicing with a saw or laser). In some cases, one or more cavity side walls 111 of a cavity 110 partially or completely filled with stabilizing material 101 can be reduced in cross-sectional thickness after the stabilizing material 101 has been added (e.g., and subsequently cured allowed to solidify), for example, as shown in step 702 of FIG. 4. For example, one or more cavities 110 formed in an ultrasound transducer wafer 102 coupled to a solid support 108 can be partially (or completely) filled with stabilizing material 101 before one or more cavity side walls 111 are etched to reduce the cross-sectional thickness of the cavity side walls 111 (e.g., to a cross-sectional thickness of 50 micrometers or less). In some cases, additional stabilizing material 101 (e.g., having a high decomposition temperature) can be added to completely fill the one or more cavities 110 or to extend beyond one or more cavity side walls 111 (e.g., to form a lens, for example as shown in FIG. 2B and FIG. 4). In some cases, stabilizing material 101 can aid in reducing a risk of ultrasound transducer wafer 102 damage when added to one or more surfaces of an ultrasound transducer wafer 102 until the stabilizing material 101 has a cross-sectional thickness of less than 5 micrometers, at least 5 micrometers, at least 10 micrometers, at least 20 micrometers, at least 30 micrometers, at least 40 micrometers, at least 50 micrometers, more than 50 micrometers, from 5 to 50 micrometers, from 20 to 50 micrometers, from 20 to 40 micrometers, or from 20 to 30 micrometers (e.g., wherein the cross-sectional thickness is measured after the stabilizing material solidifies).

In some cases, contacting one or more surfaces of an ultrasound (e.g., one or more inner surfaces of a cavity 110) with a stabilizing material 101 can comprise spin coating the stabilizing material 101 onto the one or more surfaces. In some cases, spin coating of stabilizing material 101 can be performed under vacuum conditions, e.g., to reduce or eliminate bubble formation. In some cases, contacting one or more surfaces of an ultrasound (e.g., one or more inner surfaces of a cavity 110) with a stabilizing material 101 can comprise ink jet deposition of the stabilizing material 101 onto the one or more surfaces. In some cases, ink jet deposition can be performed under vacuum conditions, e.g., to reduce or eliminate bubble formation. In some cases, contacting one or more surfaces of an ultrasound (e.g., one or more inner surfaces of a cavity 110) with a stabilizing material 101 can comprise spray deposition of the stabilizing material 101 onto the one or more surfaces. In some cases, contacting one or more surfaces of an ultrasound (e.g., one or more inner surfaces of a cavity 110) with a stabilizing material 101 can comprise chemical vapor deposition (CVD) of the stabilizing material 101 onto the one or more surfaces. In some cases, contacting one or more surfaces of an ultrasound (e.g., one or more inner surfaces of a cavity 110) with a stabilizing material 101 can comprise physical vapor deposition (PVD) of the stabilizing material 101 onto the one or more surfaces. In some cases, a mask or pattern can be used to ensure that stabilizing material 101 is deposited on intended surfaces and/or to ensure that stabilizing material 101 is not deposited on unintended surfaces. In some cases, a stabilizing material 101 can be allowed to solidify after it is added to one or more surfaces of the ultrasound transducer wafer 102. In some cases, a stabilizing material 101 can be actively caused to solidify (e.g., by curing, for example, using exposure to ultraviolet (UV) light) after it is added to one or more surfaces of the ultrasound transducer wafer 102. Ensuring that the stabilizing material 101 is free of bubbles after deposition (e.g., by depositing the stabilizing material 101 under vacuum and/or using a technique such as spray deposition, CVD, or PVD) can be ensure that the acoustic properties of the deposited stabilizing material 101 do not adversely affect the transmission of ultrasound energy through the stabilizing material 101 during ultrasound transducer device 100 operation.

In some cases, additional stabilizing material 101 can be added to an ultrasound transducer wafer 102 to cover one or more surfaces of the ultrasound transducer wafer 102 and/or a portion of solidified stabilizing material 101 after initial deposition of stabilizing material 101, for example, as shown in FIG. 4. In some cases, an acoustic lens 114 can be formed from the same material as the stabilizing material 101. For example, stabilizing material 101 added to one or more surfaces of the ultrasound transducer wafer 102 and/or a portion of solidified stabilizing material 101 after initial deposition of stabilizing material 101 can be formed into an acoustic lens 114. In some cases, an acoustic lens 114 can be coupled to one or more of an ultrasound transducer chip (e.g., comprising a plurality of cavities) singulated from the ultrasound transducer wafer and/or a stabilizing material 101 (e.g., of the ultrasound transducer chip comprising a plurality of cavities singulated from the ultrasound transducer wafer). In some cases, an acoustic lens 114 can extend across (e.g., across and above) one or more cavities of the ultrasound transducer wafer or ultrasound transducer chip.

In some cases, an ultrasound transducer wafer 102 can be decoupled from a solid support 108 after contacting the ultrasound transducer wafer 102 with stabilizing material 101 (e.g., as shown in step 910 of FIG. 2A and FIG. 2B, and in step 654 of FIG. 3). In some cases, decoupling the ultrasound transducer wafer 102 from the solid support 108 can comprise debonding the debondable adhesive. In some cases, an ultrasound transducer wafer 102 can be singulated (e.g., into one or more ultrasound transducer chips, for instance one or more ultrasound transducer chips comprising a plurality of cavities formed in the wafer and the stabilizing material) using a saw or by laser dicing.

A method of fabricating an ultrasound transducer device 100 can comprise assembling the ultrasound transducer wafer 102 comprising the stabilizing material 101 with one or more additional components of the ultrasound transducer device 100 (e.g., as shown in step 912 of FIG. 2A and step 914 of FIG. 2B). An ultrasound transducer wafer 102 (or portion thereof, such as an ultrasound transducer chip, which can be a singulated portion of an ultrasound transducer wafer) can be coupled to an application-specific circuit (ASIC) 116. As shown in FIG. 2A, the ultrasound transducer wafer 102 can be coupled to a conductor of a metal layer 117 of an ASIC 116. In some cases, the metal layer 117 of the ASIC 116 can be coupled to a conductor of a metal layer 121 of a PCB 120 by a wirebond 126, which can be soldered to each of the metal layers. In some cases, a non-conductive die attach 118 can be disposed between the ASIC 116 and the PCB 120, as shown in FIG. 2A. In some cases, an ultrasound transducer wafer 102 (or portion thereof, such as an ultrasound transducer chip) can be coupled to an ASIC 116 by flip-chip soldering. As shown in FIG. 2B, the ultrasound transducer wafer 102 can be coupled to a conductor of a metal layer 117 of an ASIC 116, which may comprise a through-silicon-via (TSV) connection 122. In some cases, the TSV connection 122 can be coupled to a conductor of a metal layer 121 of a PCB 120 by a junction, such as a flip-chip solder 124 (e.g., which may be located in a nonconducting underfill layer 119 disposed between the ASIC and PCB), as shown in FIG. 2B.

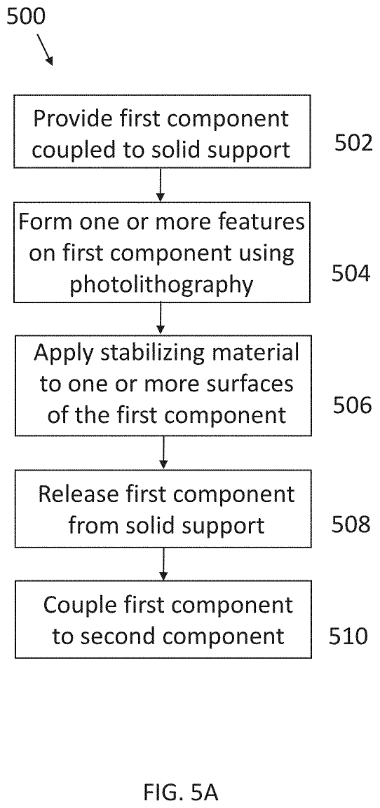

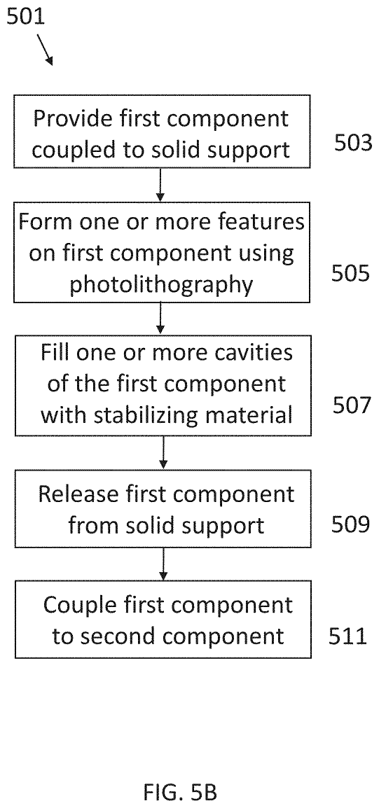

FIG. 5A shows a flow chart of a method 500 of fabricating an ultrasound transducer device 100 comprising a stabilizing material 101. Method 500 can comprise a step 502 of providing a first component (e.g., an ultrasound transducer wafer 102) coupled to a solid support 108. Then, one or more features (e.g., comprising one or more cavities 110) can be formed on the first component using photolithography, as shown in step 504. A stabilizing material 101 can be applied to one or more surfaces of the first component, as shown in step 506. As shown in step 508, the first component can be released (e.g., decoupled) from the solid support 108. Method 500 can also comprise coupling the first component to a second component (e.g., an ASIC) after applying the stabilizing material to the first component and decoupling the first component from the solid support, as shown in step 510.

FIG. 5B shows a flow chart of a method 501 of fabricating an ultrasound transducer device 100 comprising a stabilizing material 101. Method 501 can comprise a step 503 of providing a first component (e.g., an ultrasound transducer wafer 102) coupled to a solid support 108. Then, one or more features (e.g., comprising one or more cavities 110) can be formed on the first component using photolithography, as shown in step 505. A stabilizing material 101 can be used to fill one or more cavities of the first component, as shown in step 507. As shown in step 509, the first component can be released (e.g., decoupled) from the solid support 108. As shown in step 511, the method can also comprise coupling the first component to a second component (e.g., an ASIC) after applying the stabilizing material to the first component and decoupling the first component from the solid support.

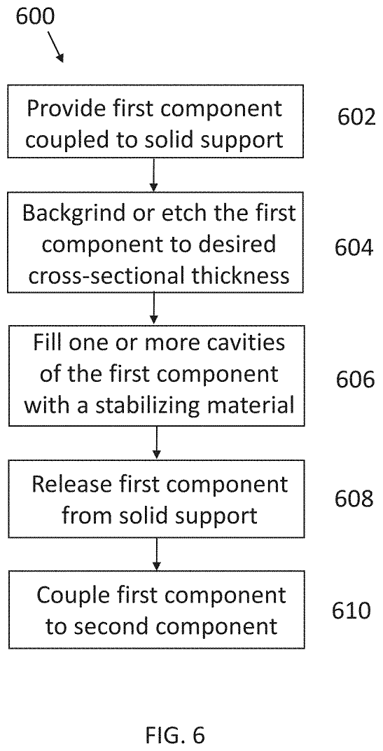

FIG. 6 shows a flow chart of a method 600 of fabricating an ultrasound transducer device 100 comprising a stabilizing material 101. Method 600 can comprise a step 602 of providing a first component (e.g., an ultrasound transducer wafer 102) coupled to a solid support 108. The first component can be etched or subjected to backgrinding to achieve a desired cross-sectional thickness in the first component, as shown in step 604. A stabilizing material 101 can be used to fill one or more cavities of the first component, as shown in step 606. As shown in step 608, the first component can be released (e.g., decoupled) from the solid support 108. As shown in step 610, the method can also comprise coupling the first component to a second component (e.g., an ASIC) after applying the stabilizing material to the first component and decoupling the first component from the solid support.

### Ultrasound Transducer Devices

An ultrasound transducer device can comprise one or more ultrasound transducers. In many cases, the one or more ultrasound transducers (e.g., and one or more other internal components, such as a MEMS array, an ultrasound transducer wafer (e.g., a MEMS wafer), an ASIC, and/or a processor) of an ultrasound system or device can be located within an internal compartment (e.g., internal space) of the ultrasound system or device. In some cases, an internal compartment or space of an ultrasound system can be surrounded by (e.g., spatially encompassed by) an outer barrier, which can comprise a housing and an acoustic lens 114. In some cases, an internal compartment or space of an ultrasound system can be defined by an outer barrier surrounding (e.g., spatially encompassing) it. In some cases, systems, devices, or methods described herein can comprise piezoelectric micromachine ultrasound transducers (pMUTs). In some cases, system, devices, or methods described herein can comprise one or more capacitive micromachine ultrasonic transducers (cMUTs). Piezoelectric micromachine ultrasound transducers (pMUTs) can be formed on a substrate, such as a semiconductor wafer (e.g., a printed circuit board, PCB). pMUT elements constructed on semiconductor substrates can offer a smaller size profile than bulky conventional transducers having bulkier piezoelectrical material. In some cases, pMUTs can also be less expensive to manufacture and/or may allow less complicated and higher performance interconnection between the transducers and additional electronics of the ultrasound device or system.

Micromachine ultrasound transducers (MUTs), which can include pMUTs and/or cMUTs can include a diaphragm (e.g., a thin membrane attached, for example at the membrane edges, to one or more portions of the interior of an imaging device (e.g., ultrasound probe)). In contrast, traditional bulk piezoelectric (PZT) elements typically consist of a single solid piece of material. Such traditional PZT ultrasound systems and devices can be expensive to fabricate, for example, because great precision is required to cut and mount PZT or ceramic material comprising the PZT ultrasound systems and devices with the proper spacing. Additionally, traditional PZT ultrasound systems and devices can have significantly higher transducer impedance compared to the impedance of the transmit/receive electronics of the PZT systems and devices, which can adversely affect performance.

In some cases, one or more transducer elements can be configured to transmit and/or receive signals at a specific frequency or bandwidth (e.g., wherein the bandwidth is associated with a center frequency). In some cases, one or more transducer elements can be further configured to transmit and/or receive signals at additional center frequencies and bandwidths. Such multi-frequency transducer elements can be referred to as multi-modal elements, and can, in some embodiments, be used to expand a bandwidth of an imaging system or device 100. A transducer element or pixel can be configured to emit (e.g., transmit) and/or receive an ultrasonic energy (e.g., an ultrasonic waveform, pattern, or pressure wave) at a suitable center frequency, e.g., from 0.1 megahertz (MHz) to 100 MHz. In some cases, a transducer or pixel can be configured to transmit or receive ultrasonic energy at a center frequency of 0.1 MHz to 1 MHz, 0.1 MHz to 1.8 MHz, 0.1 MHz to 3.5 MHz, 0.1 MHz to 5.1 MHz, 0.1 MHz to 10 MHz, 0.1 MHz to 25 MHz, 0.1 MHz to 50 MHz, 0.1 MHz to 100 MHz, 1 MHz to 1.8 MHz, 1 MHz to 3.5 MHz, 1 MHz to 5.1 MHz, 1 MHz to 10 MHz, 1 MHz to 25 MHz, 1 MHz to 50 MHz, 1 MHz to 100 MHz, 1.8 MHz to 3.5 MHz, 1.8 MHz to 5.1 MHz, 1.8 MHz to 10 MHz, 1.8 MHz to 25 MHz, 1.8 MHz to 50 MHz, 1.8 MHz to 100 MHz, 3.5 MHz to 5.1 MHz, 3.5 MHz to 10 MHz, 3.5 MHz to 25 MHz, 3.5 MHz to 50 MHz, 3.5 MHz to 100 MHz, 5.1 MHz to 10 MHz, 5.1 MHz to 25 MHz, 5.1 MHz to 50 MHz, 5.1 MHz to 100 MHz, 10 MHz to 25 MHz, 10 MHz to 50 MHz, 10 MHz to 100 MHz, 25 MHz to 50 MHz, 25 MHz to 100 MHz, or 50 MHz to 100 MHz. In some cases, a transducer or pixel can be configured to transmit or receive ultrasonic energy at a center frequency of 0.1 MHz, 1 MHz, 1.8 MHz, 3.5 MHz, 5.1 MHz, 10 MHz, 25 MHz, 50 MHz, or 100 MHz. In some cases, a transducer or pixel can be configured to transmit or receive ultrasonic energy at a center frequency of at least 0.1 MHz, 1 MHz, 1.8 MHz, 3.5 MHz, 5.1 MHz, 10 MHz, 25 MHz, 50 MHz, or 100 MHz. In some cases, a transducer or pixel can be configured to transmit or receive ultrasonic energy at a center frequency of at most 0.1 MHz, 1 MHz, 1.8 MHz, 3.5 MHz, 5.1 MHz, 10 MHz, 25 MHz, 50 MHz, or 100 MHz.

### Junctions

A first component of an ultrasound transducer device (e.g., a printed circuit board or portion thereof) can be coupled to one or more second components of the ultrasound transducer device by a junction. In some cases, a junction can provide an electrical connection between the first component and the one or more second components. For instance, a junction can electrically couple the first component with the one or more second components, in some cases. A junction that couples a first component of an ultrasound device and one or more second components of the ultrasound device can be electrically conductive (e.g., wherein the junction comprises a conductor). For instance, a junction can comprise an electrically conductive material. In some cases, a junction can physically join and/or stabilize a joint between the first component and the second component.

A junction of an ultrasound transducer device can comprise one or more wires (e.g., one or more wirebonds). In some cases, a first end of a wirebond can be coupled to a terminal of an ASIC and a second end of the wirebond can be coupled to a printed circuit board (PCB). In some cases, a wirebond can be coupled to one or more other components (e.g., an ASIC and/or a PCB) of an ultrasound transducer device via soldering. In some cases, a wire can comprise a conductor. For example, a wire can comprise copper wire, gold wire, silver wire, aluminum wire, or an alloy thereof (e.g., magnesium-aluminum or silicon-aluminum wire). In some cases, a wire can be coated (e.g., palladium-coated wire) and/or doped (e.g., wherein the wire is doped with beryllium).

An ultrasound transducer device can comprise one or more “through-silicon via” (TSV) connections. In some cases, a TSV connection can electrically couple an ASIC to a PCB. In some cases, a TSV can be coupled to one or more additional components of an ultrasound transducer device via a soldering method, such as flip-chip soldering. A TSV connection can comprise an electrically conductive material that passes from a first (e.g., distal) surface of a wafer (e.g., a silicon wafer, for example of an integrated circuit, such as an ASIC wafer) to a second (e.g., proximal) surface of the wafer. In some cases, a junction can comprise solder (e.g., at one or more solder points, for example, of a TSV connection or a wirebond connection).

A junction of an ultrasound transducer device can comprise solder. A solder can be useful in stabilizing or connecting one or more other components of the junction (e.g., a wirebond, a TSV, and/or a metal layer of an ASIC or a PCB). A solder can have a reflow temperature. In some cases, a solder can melt from a solid phase to a liquid or semi-liquid phase when its temperature reaches the reflow temperature. In some cases, a method for fabricating an ultrasound transducer device can comprise bringing all or a portion of the ultrasound transducer device to a temperature equal to the reflow temperature of the solder (e.g., to melt the solder for application to the junction). In some cases, a method for fabricating an ultrasound transducer device can comprise maintaining the ultrasound transducer device and/or one of, a plurality of, or all of its components at temperature(s) that are substantially equal to or below (e.g., temperatures that do not exceed) the reflow temperature. In some cases, a reflow temperature of a solder can be up to 240° C.

### Stabilizing Material

As described herein, the occurrence of damage to ultrasound device components sustained during fabrication can be greatly reduced by specifying the materials, methods, and/or order of steps used in the fabrication of an ultrasound transducer device 100. For instance, adding (e.g., partially or completely coating or filling) a material (e.g., a stabilizing material 101) one or more surfaces or cavities of an ultrasound transducer wafer 102 (e.g., before the ultrasound transducer wafer 102 is removed from a solid support to which it is coupled) can substantially reduce the likelihood and/or extent to which ultrasound transducer wafer 102 is damaged during fabrication. In some cases, all or a portion of the ultrasound transducer wafer 102 can be brought to (e.g., reduced to) a desired cross-sectional thickness (e.g., via grinding), etched to comprise a desired surface architecture (e.g., using lithographic technique(s) to create transducer cavities 110), and contacted (e.g., partially or completely coated or filled) with a material (e.g., a stabilizing material 101) capable of stabilizing the ultrasound transducer wafer 102 before removing the wafer 102 from a solid support 108. For example, an ultrasound transducer wafer 102 can be etched to comprise a desired architecture (e.g., comprising a plurality of cavities 110) can be partially filled with a material capable of stabilizing the processed array prior to modification of the thickness of the transducer wafer 102 (e.g., thinning of the cavity walls to a desired thickness, for example, via lithography).

In some cases, a stabilizing material 101 can be a material capable of flowing onto or into a surface or feature of the component. For instance, a stabilizing material can be melted and applied to a surface of the component (e.g., an interior surface of a cavity 110 of the component, such as an inner surface of a bottom wall 112 of a cavity 110 in an ultrasound transducer wafer 102 or a surface of a cavity side wall 111) and allowed to set (e.g., harden or dry) before the component is subjected to a manipulation step of the fabrication process. In some cases, a stabilizing material can be a flowable material that is applied to a surface of the component (e.g., an interior surface of a cavity of the component) and cured (e.g., using ultraviolet light) before the component is subjected to a manipulation step of the fabrication process. In some cases, adding a stabilizing material to all or a portion of an ultrasound transducer wafer 102 can decrease the risk of damage to the ultrasound transducer wafer 102 (e.g., as a result of forces experienced by the ultrasound transducer wafer 102 during ultrasound transducer device 100 fabrication), for instance, if all or a portion of the ultrasound transducer wafer 102 (e.g., to which the stabilizing material 101 is added) has a reduced cross-sectional thickness (e.g., a cross-sectional thickness of 50 micrometers or less, 40 micrometers or less, 30 micrometers or less, or 20 micrometers or less).

In some cases, a stabilizing material 101 can meet or exceed acoustic requirements for an acoustic lens 114 used in an ultrasound transducer device 100. In some cases, a stabilizing material 101 can have a sound speed higher than or substantially the same as that of a material used to form an acoustic lens 114. In some cases, a stabilizing material 101 can have an acoustic attenuation less than or substantially the same as that of a material used to form an acoustic lens 114. In some cases, a stabilizing material 101 can have an acoustic impedance less than or substantially the same as that of an acoustic lens 114. In some cases, a stabilizing material 101 can be used to form an acoustic lens 114 of an ultrasound transducer device 100 described herein.

A stabilizing material 101 can comprise a monomer. In some cases, a stabilizing material 101 can comprise silicone (e.g., a silicone-based monomer). In some cases, a stabilizing material 101 can comprise a polymer. In some cases, a monomer of a stabilizing material 101 can be polymerized into a polymer. In some cases, polymerizing a stabilizing material 101 can comprise cross-linking all or a portion of the molecules (e.g., monomers) comprising the stabilizing material 101. In some cases, a monomer of a stabilizing material 101 can be polymerized by exposing the stabilizing material 101 to ultraviolet (UV) light (e.g., light with a wavelength from 315 nanometers to 430 nanometers). In some cases, a stabilizing material 101 can be polymerized using a polymerization agent or a catalyst (e.g., a UV-activated platinum catalyst). For example, a stabilizing material 101 may be polymerized by mixing the stabilizing material 101 with a polymerization initiator, in some cases. In some cases, polymerizing the stabilizing material 101 can partially or completely cure the stabilizing material (e.g., wherein the stabilizing material 101 is solidified or caused to partially or completely transition from a liquid state to a solid state or from a semi-solid state to a solid state). In some cases, polymerizing the stabilizing material 101 can be performed at the same time as contacting the ultrasound transducer wafer 102 (or a portion thereof) with the stabilizing material 101. In some cases, polymerizing the stabilizing material 101 can be performed after contacting the ultrasound transducer wafer 102 (or a portion thereof) with the stabilizing material 101.

In some cases, a stabilizing material 101 can be subjected to a curing or polymerization process (e.g., comprising exposure to UV light) for a curing time. A curing time can depend on the composition and/or the amount of stabilizing material 101 that is being cured (or polymerized). For example, curing conditions comprising exposing the stabilizing material 101 to an ultraviolet light can comprise exposing the stabilizing material 101 to ultraviolet light for 1 hour or less, 30 minutes or less, 15 minutes or less, 10 minutes or less, 5 minutes or less, 4 minutes or less, 3 minutes or less, 2 minutes or less, 1 minute or less, 45 seconds or less, 30 seconds or less, 15 seconds or less, 10 seconds or less, 5 seconds or less, or 1 second or less. In some cases, curing or polymerizing a stabilizing material 101 can comprise increasing the temperature of the stabilizing material 101. In some cases, increasing the temperature of the stabilizing material 101 can be an advantageous curing condition, for example, in that the curing or polymerization process can be performed more quickly at increased temperatures, in some cases. In some cases, curing or polymerizing a stabilizing material 101 can be performed at a temperature of from 100° C. to 18° C., from 80° C. to 20° C., from 80° C. to 25° C., from 80° C. to 35° C., from 80° C. to 45° C., from 80° C. to 55° C., from 80° C. to 65° C. from 60° C. to 20° C., from 60° C. to 25° C., from 60° C. to 35° C., or from 60° C. to 45° C. In some cases, curing or polymerizing a stabilizing material 101 can comprise increasing the humidity in the environment of the stabilizing material 101 (e.g., beyond ambient humidity) during a step of polymerization or curing, e.g., to increase the speed of curing or polymerization. In some cases, curing or polymerizing a stabilizing material can comprise decreasing the oxygen content in the environment of a stabilizing material 101 (e.g., beyond ambient oxygenation) during a step of polymerization or curing, e.g., to increase the speed of curing or polymerization.

In some cases, a step of polymerizing a stabilizing material 101 (e.g., wherein the stabilizing material 101 is exposed to UV light) can be performed after contacting one or more inner surfaces of an ultrasound transducer wafer 102 (e.g., one or more surfaces of a cavity 110 of an ultrasound transducer wafer 102) with the stabilizing material 101 (e.g., wherein the stabilizing material 101 comprises a monomer, such as a silicone-based monomer). In some cases, a step of polymerizing a stabilizing material 101 (e.g., wherein the stabilizing material 101 is exposed to UV light) can be performed during a step of contacting one or more inner surfaces of an ultrasound wafer 102 (e.g., one or more surfaces of a cavity 110 of an ultrasound transducer wafer 102) with the stabilizing material 101 (e.g., wherein the stabilizing material 101 comprises a monomer, such as a silicone-based monomer).

A stabilizing material 101 can comprise silicone. In some cases, a stabilizing material 101 can comprise one or more additives (e.g., heat-stabilizing additives). In some cases, a stabilizing material 101 comprising one or more additives (e.g., one or more heat-stabilizing additives) can have a higher decomposition temperature. In some cases, it is possible to increase a decomposition temperature of a stabilizing material by up to 10° C., up to 20° C., up to 30° C., up to 40° C., up to 50° C., up to 60° C., up to 70° C., up to 80° C., up to 90° C., up to 100° C., up to 110° C., or up to 120° C. by adding one or more additives (e.g., heat-stabilizer additives) to the stabilizing material 101. In some cases, a stabilizing material 101 comprising one or more additives (e.g., heat-stabilizing additives) to have a decomposition temperature of up to 180° C., up to 200° C., up to 210° C., up to 220° C., up to 230° C., up to 240° C., up to 250° C., up to 260° C., up to 270° C., up to 280° C., or more than 280° C. In some cases, a stabilizing material 101 comprising one or more additives (e.g., heat-stabilizing additives) to have a decomposition temperature of higher than 180° C., higher than 200° C., higher than 210° C., higher than 220° C., higher than 230° C., higher than 240° C., higher than 250° C., higher than 260° C., higher than 270° C., or higher than 280° C. Some heat-stabilizing additives useful in stabilizing materials 101 include iron, cerium, and titanium oxide. In some cases, a heat-stabilizing additive can have a particle size of 10 micrometers or less.

In many cases, materials used to form acoustic lenses in existing ultrasound transducer devices have a decomposition temperature below solder reflow temperatures. In many cases, a stabilizing material 101 having a higher decomposition temperature than a solder reflow temperature (e.g., of a solder used in the fabrication of the ultrasound transducer device 100) can be used in methods and systems described herein. In some cases, using a stabilizing material 101 having a higher decomposition temperature than a solder reflow temperature can reduce the risk of the stabilizing material being adversely affected (e.g., with respect to acoustic clarity and/or melting) by ultrasound transducer device fabrication steps subsequent to addition of the stabilizing material to the ultrasound transducer wafer. For example, using a stabilizing material 101 having a higher decomposition temperature than a reflow temperature of a solder used to couple an ASIC to a PCB after the stabilizing material 101 is added to the ultrasound transducer wafer 102 can prevent melting or degradation of the stabilizing material 101 when heat is added to couple the ASIC to the PCB during fabrication.

A stabilizing material 101 can exhibit a low acoustic attenuation (e.g., after addition to a silicon-based wafer or portion thereof and curing). For example, a stabilizing material 101 can have an acoustic attenuation of about 0.10 decibels per millimeter (dB/mm) to about 50.0 dB/mm. In some cases, a stabilizing material 101 can have an acoustic attenuation of about 0.10 dB/mm to about 0.25 dB/mm, about 0.10 dB/mm to about 0.50 dB/mm, about 0.10 dB/mm to about 0.75 dB/mm, about 0.10 dB/mm to about 1.00 dB/mm, about 0.10 dB/mm to about 5.00 dB/mm, about 0.10 dB/mm to about 10 dB/mm, about 0.10 dB/mm to about 15.0 dB/mm, about 0.10 dB/mm to about 20.0 dB/mm, about 0.10 dB/mm to about 25.0 dB/mm, about 0.10 dB/mm to about 30.0 dB/mm, about 0.10 dB/mm to about 50.0 dB/mm, about 0.25 dB/mm to about 0.50 dB/mm, about 0.25 dB/mm to about 0.75 dB/mm, about 0.25 dB/mm to about 1.00 dB/mm, about 0.25 dB/mm to about 5.00 dB/mm, about 0.25 dB/mm to about 10.0 dB/mm, about 0.25 dB/mm to about 15.0 dB/mm, about 0.25 dB/mm to about 20.0 dB/mm, about 0.25 dB/mm to about 25.0 dB/mm, about 0.25 dB/mm to about 30.0 dB/mm, about 0.25 dB/mm to about 50.0 dB/mm, about 0.50 dB/mm to about 0.75 dB/mm, about 0.50 dB/mm to about 1.00 dB/mm, about 0.50 dB/mm to about 5.00 dB/mm, about 0.50 dB/mm to about 10.0 dB/mm, about 0.50 dB/mm to about 15 dB/mm, about 0.50 dB/mm to about 20.0 dB/mm, about 0.50 dB/mm to about 25.0 dB/mm, about 0.50 dB/mm to about 30.0 dB/mm, about 0.50 dB/mm to about 50.0 dB/mm, about 0.75 dB/mm to about 1.00 dB/mm, about 0.75 dB/mm to about 5.00 dB/mm, about 0.75 dB/mm to about 10.0 dB/mm, about 0.75 dB/mm to about 15.0 dB/mm, about 0.75 dB/mm to about 20.0 dB/mm, about 0.75 dB/mm to about 25.0 dB/mm, about 0.75 dB/mm to about 30.0 dB/mm, about 0.75 dB/mm to about 50.0 dB/mm, about 1.00 dB/mm to about 5.00 dB/mm, about 1.00 dB/mm to about 10.0 dB/mm, about 1.00 dB/mm to about 15.0 dB/mm, about 1.00 dB/mm to about 20.0 dB/mm, about 1.00 dB/mm to about 25.0 dB/mm, about 1.00 dB/mm to about 30.0 dB/mm, about 1.00 dB/mm to about 50.0 dB/mm, about 5.00 dB/mm to about 10.0 dB/mm, about 5.00 dB/mm to about 15.0 dB/mm, about 5.00 dB/mm to about 20.0 dB/mm, about 5.00 dB/mm to about 25.0 dB/mm, about 5.00 dB/mm to about 30.0 dB/mm, about 5.00 dB/mm to about 50.0 dB/mm, about 10.0 dB/mm to about 15.0 dB/mm, about 10.0 dB/mm to about 20.0 dB/mm, about 10.0 dB/mm to about 25.0 dB/mm, about 10.0 dB/mm to about 30.0 dB/mm, about 10.0 dB/mm to about 50.0 dB/mm, about 15.0 dB/mm to about 20.0 dB/mm, about 15.0 dB/mm to about 25.0 dB/mm, about 15.0 dB/mm to about 30.0 dB/mm, about 15.0 dB/mm to about 50.0 dB/mm, about 20.0 dB/mm to about 25.0 dB/mm, about 20.0 dB/mm to about 30.0 dB/mm, about 20.0 dB/mm to about 50.0 dB/mm, about 25.0 dB/mm to about 30.0 dB/mm, about 25.0 dB/mm to about 50.0 dB/mm, or about 30.0 dB/mm to about 50.0 dB/mm. In some cases, a stabilizing material 101 can have an acoustic attenuation of about 0.10 dB/mm, about 0.25 dB/mm, about 0.50 dB/mm, about 0.75 dB/mm, about 1.00 dB/mm, about 5.00 dB/mm, about 10.0 dB/mm, about 15.0 dB/mm, about 20.0 dB/mm, about 25.0 dB/mm, about 30.0 dB/mm, or about 50.0 dB/mm. In some cases, a stabilizing material 101 can have an acoustic attenuation of at least about 0.10 dB/mm, at least about 0.25 dB/mm, at least about 0.50 dB/mm, at least about 0.75 dB/mm, at least about 1.00 dB/mm, at least about 5.00 dB/mm, at least about 10.0 dB/mm, at least about 15.0 dB/mm, at least about 20.0 dB/mm, at least about 25.0 dB/mm, at least about 30.0 dB/mm, or at least about 50.0 dB/mm. In some cases, a stabilizing material 101 can have an acoustic attenuation of at most about 0.10 dB/mm, at most about 0.25 dB/mm, about 0.50 dB/mm, about 0.75 dB/mm, about 1.00 dB/mm, about 5.00 dB/mm, about 10.0 dB/mm, about 15.0 dB/mm, about 20.0 dB/mm, about 25.0 dB/mm, about 30.0 dB/mm, or about 50.0 dB/mm. A stabilizing material 101 having a low acoustic attenuation (e.g., after addition to at least a portion of a silicon-based wafer or portion thereof) can improve the transmission of acoustic (e.g., ultrasound) energy waves through the stabilizing material 101, e.g., during operation of the ultrasound transducer device 100.

### Applications

In some cases, an imaging system or device 100 described herein can be used in (e.g., non-invasive) medical imaging, lithotripsy, localized tissue heating for therapeutic interventions, highly intensive focused ultrasound (HIFU) surgery, and/or non-medical uses flow measurements in pipes (or speaker and microphone arrays). In some cases, an imaging system or device described herein can be used to determine direction and/or velocity of fluid flow (e.g., blood flow) in arteries and/or veins, for example using Doppler mode imaging. In some cases, an imaging system or device described herein can be used to measure tissue stiffness.

In some cases, an imaging system or device 100 described herein can be configured to perform one-dimensional imaging (e.g., A-Scan imaging). In some cases, an imaging system or device 100 described herein can be configured to perform two-dimensional imaging (e.g., B-Scan imaging). In some cases, an imaging system or device 100 described herein can be configured to perform three-dimensional imaging (e.g., C-Scan imaging). In some cases, an imaging system or device 100 described herein can be configured to perform Doppler imaging. In some cases, an imaging system or device 100 described herein may be switched to a different mode (e.g., between modes), including linear mode or sector mode. In some cases, an imaging system or device 100 can be electronically configured under program control (e.g., by a user).

In many cases, an imaging system or device 100 (e.g., a probe of an imaging system or device 100) can be portable. For instance, an imaging system or device 100 can comprise (e.g., house within a housing) a handheld casing, which can house one or more transducer elements, pixels, or arrays, ASICs, control circuitry, and/or a computing device. In some case, an imaging system or device 100 can comprise a battery.

### Some Definitions

Unless otherwise defined, all technical terms used herein have the same meaning as commonly understood by one of ordinary skill in the art to which the present subject matter belongs.

As used in this specification and the appended claims, the singular forms “a,” “an,” and “the” include plural references unless the context clearly dictates otherwise. Any reference to “or” herein is intended to encompass “and/or” unless otherwise stated.

Reference throughout this specification to “some embodiments,” “further embodiments,” or “a particular embodiment,” means that a particular feature, structure, or characteristic described in connection with the embodiment is included in at least one embodiment. Thus, the appearances of the phrase “in some embodiments,” or “in further embodiments,” or “in a particular embodiment” in various places throughout this specification are not necessarily all referring to the same embodiment. Furthermore, the particular features, structures, or characteristics may be combined in any suitable manner in one or more embodiments.

While preferred embodiments of the present subject matter have been shown and described herein, it will be obvious to those skilled in the art that such embodiments are provided by way of example only. Numerous variations, changes, and substitutions will now occur to those skilled in the art without departing from the present subject matter. It should be understood that various alternatives to the embodiments of the present subject matter described herein may be employed in practicing the present subject matter.

1. A method of fabricating an ultrasound transducer device, the method comprising:
forming a plurality of cavities in a transducer wafer coupled to a carrier substrate;
contacting one or more inner surfaces of one or more of the plurality of cavities with a stabilizing material; and
decoupling the transducer wafer from the carrier substrate after contacting the one or more inner surfaces with the stabilizing material.

2. The method of claim 1, further comprising reducing a cross-sectional thickness of at least a portion of the transducer wafer.

3. The method of claim 2, wherein the cross-sectional thickness of the transducer wafer is reduced to no more than 75 micrometers.

4. (canceled)

5. The method of claim 2, wherein reducing the cross-sectional thickness of at least a portion of the transducer wafer is performed before forming the plurality of cavities in the transducer wafer.

6. The method of claim 2, wherein reducing the cross-sectional thickness of at least a portion of the transducer wafer is performed after forming the plurality of cavities in the transducers wafer.

7. The method of claim 2, wherein reducing the cross-sectional thickness of at least a portion of the transducer wafer is performed after contacting the one or more inner surfaces with the stabilizing material.

8. The method of claim 2, wherein reducing the cross-sectional thickness of at least a portion of the transducer wafer is performed before contacting the one or more inner surfaces with the stabilizing material.

9.-16. (canceled)

17. The method of claim 1, wherein contacting one or more inner surfaces with the stabilizing material comprises one or more of spin coating, ink jet deposition, spray deposition, physical vapor deposition (PVD), or chemical vapor deposition (CVD).

18. The method of claim 1, further comprising polymerizing the stabilizing material.

19.-21. (canceled)

22. The method of claim 1, wherein contacting one or more inner surfaces with stabilizing material comprises filling the one or more cavities with stabilizing material until the stabilizing material is even with the height of one or more cavity side walls of the one or more cavities.

23. The method of claim 1, wherein contacting one or more inner surfaces with stabilizing material comprises filling the one or more cavities with stabilizing material until the stabilizing material exceeds the height of one or more cavity side walls of the one or more cavities.

24. The method of claim 1, wherein contacting one or more inner surfaces with stabilizing material comprises filling the one or more cavities with stabilizing material until the stabilizing material less than the height of one or more cavity side walls of the one or more cavities.

25. The method of claim 1, further comprising singulating the transducer wafer into one or more ultrasound transducer chips comprising the plurality of cavities and the stabilizing material; and coupling an acoustic lens coupled to one or more of the stabilizing material or a transducer chip of the one or more ultrasound transducer chips.

26. The method of claim 25, wherein the acoustic lens extends above and across each of the one or more cavities.

27. The method of claim 25, wherein the acoustic lens is formed from the same material as the stabilizing material.

28. The method of claim 25, wherein the acoustic lens is formed from a material different than the stabilizing material.

29. The method of claim 25, wherein the ultrasound lens is formed from a lens material, and wherein the lens material and the stabilizing material have one or more of a sound speed, acoustic attenuation, or acoustic impedance that are substantially the same.

30. The method of claim 1, further comprising coupling one or more ultrasound transducer chips comprising the plurality of cavities and the stabilizing material singulated from the transducer wafer to an application-specific integrated circuit (ASIC).

31.-32. (canceled)

33. The method of claim 30, further comprising coupling the ASIC to a printed circuit board (PCB).

34.-35. (canceled)

36. The method of claim 1, wherein the stabilizing material comprises silicone.

37. The method of claim 36, wherein the stabilizing material comprises one or more heat stabilizer additives selected from iron, cerium, and titanium oxide.

38. The method of claim 1, wherein the stabilizing material has a decomposition temperature higher than 240° C.

39.-40. (canceled)

41. An ultrasound transducer device comprising:
a transducer chip comprising a plurality of cavities;
a stabilizing material in contact with at least a portion of an inner surface of one or more of the plurality of cavities;
an acoustic lens extending above and across the plurality of cavities and formed from a lens material,
wherein the lens material and the stabilizing material have one or more of a sound speed, acoustic attenuation, or acoustic impedance that are substantially the same.

42. (canceled)

43. The device of claim 41, further comprising an application-specific integrated circuit (ASIC) and a printed circuit board (PCB), wherein the ASIC is coupled to the PCB by a junction comprising a solder.

44. The device of claim 43, wherein a decomposition temperature of the stabilizing material is greater than a reflow temperature of the solder.

45. The device of claim 43, wherein the reflow temperature of the solder is 240° C.

46. The device of claim 41, wherein the stabilizing material comprises one or more heat stabilizer additives selected from iron, cerium, and titanium oxide.

47.-53. (canceled)
